(19) United States
(12) Patent Application Publication
(10) Pub. No.: US 2023/0157048 A1
(43) Pub. Date: May 18, 2023

(54) LIGHT-EMITTING ELEMENT

(71) Applicant: SHARP KABUSHIKI KAISHA, Sakai City, Osaka (JP)

(72) Inventor: TAKAYUKI NAKA, Sakai City, Osaka (JP)

(21) Appl. No.: 17/915,081

(22) PCT Filed: Mar. 19, 2021
(86) PCT No.: PCT/JP2021/011428

§ 371 Date: Sep. 27, 2022

(30) Foreign Application Priority Data
Apr. 15, 2020 (JP) PCT/JP2020/016578

(51) Int. Cl. H10K 50/15; H10K 50/17; H10K 85/60; H01L 33/14; H01L 33/26

(52) U.S. Cl. CPC H10K 50/15; H10K 50/17; H10K 85/6572; H10K 85/652; H01L 33/14; H01L 33/26; H10K 2102/351

(57) ABSTRACT

A light-emitting element includes: anode; a cathode; a light-emitting layer, and containing a light-emitting material; a hole-transport layer, and containing an organic hole-transport material; a hole-injection layer disposed between the anode and the hole-transport layer, and containing an inorganic hole-transport material; and an organic layer disposed between the hole-transport layer and the hole-injection layer. The organic layer contains an aromatic compound having: a functional group R¹ capable of chemically bonding to the inorganic hole-transport material; a functional group R² that is a functional group containing at an end at least one selected from a hydrogen atom, a nitro group, a cyano group, a halogen group, a carboxyl group, an aldehyde group, a hydroxyl group, an ester bond with one to three carbons, an alkyl group with one to three carbons or an amid group; and an aromatic ring to which each of the R¹ and the R² bonds.

### TECHNICAL FIELD

The present invention relates to a light-emitting element.

### Background Art

Patent Document 1 discloses, as an example, a light-emitting element including: a hole-injection layer made of a metal oxide; and a hole-transport layer made of an organic hole-transport material.

### CITATION LIST

### Patent Literature

[Patent Document 1] Japanese Unexamined Patent Application Publication No. 2014-067868

### SUMMARY OF INVENTION

### Technical Problem

The light-emitting element described in Patent Document 1 would have difficulty in, for example, improving luminance.

A main object of the present disclosure is to provide a light-emitting element with improved luminance.

### Solution to Problem

A light-emitting element according to an embodiment of the present disclosure includes: a first anode; a first cathode facing the first anode; a first light-emitting layer disposed between the first anode and the first cathode, and containing a first light-emitting material; a first hole-transport layer disposed between the first light-emitting layer and the first anode, and containing a first organic hole-transport material; a first hole-injection layer disposed between the first anode and the first hole-transport layer, and containing a first inorganic hole-transport material; and a first organic layer disposed between the first hole-transport layer and the first hole-injection layer, wherein the first organic layer contains a first aromatic compound having: R¹ containing at an end a functional group capable of chemically bonding to the first inorganic hole-transport material; a functional group R² that is a functional group containing at an end at least one selected from a hydrogen atom, a nitro group, a cyano group, a halogen group, a carboxyl group, an aldehyde group, a hydroxyl group, an ester bond with one to three carbons, or an alkyl group and an amid group with one to three carbons; and an aromatic ring to which each of the R¹ and the R² bonds.

### BRIEF DESCRIPTION OF DRAWINGS

FIG. 1 is a view schematically illustrating an example of a multilayer structure of a light-emitting element according to a first embodiment.

FIG. 2 is a flowchart showing an example of how to produce the light-emitting element according to the first embodiment.

FIG. 3 is a graph illustrating luminance-current characteristics of light-emitting elements according to Examples 1 to 3 and Comparative Example 1.

FIG. 4 is a graph illustrating drive voltage-current characteristics of the light-emitting elements according to Examples 1 to 3 and Comparative Example 1.

FIG. 5 is a graph illustrating luminance-current characteristics of light-emitting elements according to Comparative Examples 2 to 5.

FIG. 6 is a graph illustrating drive voltage-current characteristics of the light-emitting elements according to Comparative Examples 2 to 5.

FIG. 7 is a view schematically illustrating an example of a multilayer structure of a light-emitting element according to a second embodiment.

FIG. 8 is a view schematically illustrating an example of a multilayer structure of a light-emitting element according to a third embodiment.

FIG. 9 is a graph illustrating luminance-current characteristics of light-emitting elements according to Examples 5 and 6, and Comparative Example 6.

FIG. 10 is a graph illustrating drive voltage-current characteristics of the light-emitting elements according to Examples 5 and 6, and Comparative Example 6.

FIG. 11 is a graph illustrating luminance-power consumption of the light-emitting elements according to Examples 5 and 6, and Comparative Example 6.

FIG. 12 is a view schematically illustrating an example of a multilayer structure of a light-emitting element according to a fourth embodiment.

FIG. 13 is a graph illustrating luminance-current characteristics of light-emitting elements according to Examples 7 and 8, and Comparative Example 7.

FIG. 14 is a graph illustrating drive voltage-current characteristics of the light-emitting elements according to Examples 7 and 8, and Comparative Example 7.

FIG. 15 is a graph illustrating luminance-power consumption of the light-emitting elements according to Examples 7 and 8, and Comparative Example 7.

### DESCRIPTION OF EMBODIMENTS

From now on, examples of preferable embodiments according to the present invention are described. Note that the embodiments below are mere examples. The present invention shall not be limited to the embodiments below. Note that like reference numerals designate identical or substantially identical components, and redundant descriptions of such components would be omitted.

### First Embodiment

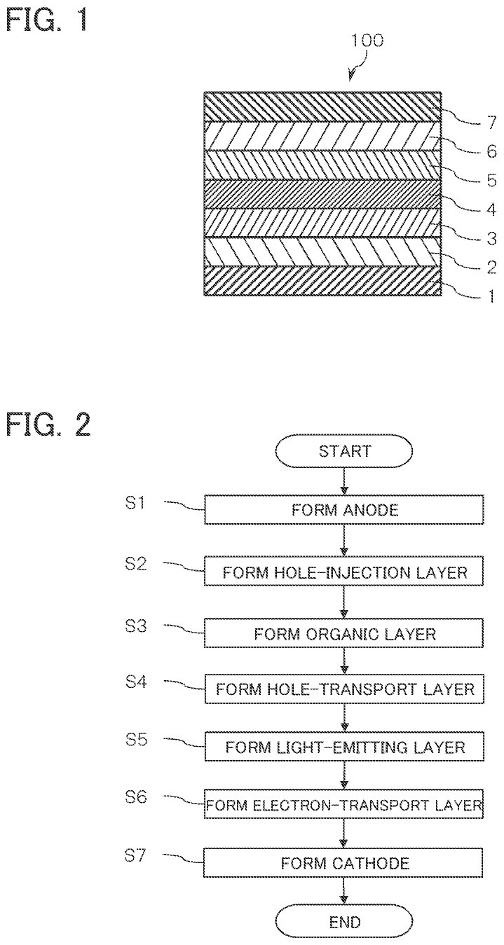

FIG. 1 is a view schematically illustrating an example of a multilayer structure of a light-emitting element 100 according to this embodiment.

As illustrated in FIG. 1, the light-emitting element 100 includes, for example, an anode (a first anode) 1, a hole-injection layer (a first hole-injection layer) 2, an organic layer (a first organic layer) 3, a hole-transport layer (a first hole-transport layer) 4, a light-emitting layer (a first light-emitting layer) 5, an electron-transport layer 6, and a cathode 7, all of which are stacked one another in the stated order. A plurality of the light-emitting elements 100 can constitute a display device.

The anode 1 supplies holes to the light-emitting layer 5.

The cathode 7 supplies electrons to the light-emitting layer 5. Moreover, the cathode 7 and the anode 2 are provided to face each other.

Either the anode 1 or the cathode 7 is made of a light-transparent material. Note that either the anode 1 or the cathode 7 may be made of a light-reflecting material. If the light-emitting element 100 is a top-emission light-emitting element, for example, the cathode 7 provided above is formed of a light-transparent material, and the anode 1 provided below is formed of a light-reflecting material. Moreover, if the light-emitting element 100 is a bottom-emission light-emitting element, for example, the cathode 7 provided above is formed of a light-reflecting material, and the anode 1 provided below is formed of a light-transparent material. Furthermore, either the anode 1 or the cathode 7 may be a multilayer stack made of a light-transparent material and a light-reflecting material, so that the anode 1 or the cathode 7 is a light-reflecting electrode.

As the light-transparent material, for example, a transparent conductive material can be used. Specific Examples of the light-transparent material may include indium tin oxide (ITO), indium zinc oxide (IZO), tin oxide (SnO₂), and fluorine-doped tin oxide (FTO). Because these materials have a high transmittance of visible light, the light-emitting element 100 improves in emission efficiency.

As a light-reflecting material, for example, a metal material can be used. Specific examples of the light-reflecting material may include aluminum (Al), silver (Ag), copper (Cu), and gold (Au). Because these materials have a high reflectance of visible light, the light-emitting element 100 improves in emission efficiency.

The light-emitting layer 5 is disposed between the anode 1 and the cathode 7, and emits light. The light-emitting layer 5 contains a light-emitting material. The light-emitting material emits light by, for example, recombination of the holes transported from the anode 1 and the electrons transported from the cathode 7. Specifically, a voltage or a current is applied between the anode 1 and the cathode 7, and the transported holes and electrons recombine together in the light-emitting layer 5. Thus, the light is released.

An example of the light-emitting material includes quantum dots. The quantum dots are semiconductor fine particles having a particle size of, for example, 100 nm or less. The quantum dots can have: a II-VI semiconductor compound such as MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, or HgTe; and/or crystals of a III-V semiconductor compound such as GaAs, GaP, InN, InAs, InP, or InSb; and/or crystals of a IV semiconductor compound such as Si or Ge. Moreover, the quantum dots may have a core/shell structure including the above semiconductor crystals as cores coated with a shell material having a high bandgap. Furthermore, the quantum dots may have ligands to be adsorbed (coordinated) onto the surface of the quantum dots.

The hole-transport layer 4 is disposed between the anode 1 and the light-emitting layer 5, and transports the holes from the anode 1 to the light-emitting layer 5. The hole-transport layer 4 contains an organic hole-transport material (a first organic hole-transport material).

The organic hole-transport material can be appropriately selected from materials typically used in this field. Examples of the materials include: such materials as 4,4′,4″-tris(9-carbazolyl)triphenylamine (TCTA), 4,4′-bis[N-(1-naphthyl)-N-phenylamino]biphenyl (NPB), zinc phthalocyanine (ZnPC), di-[4-(N,N-ditolyl-amino)-phenyl]cyclohexane (TAPC), 4,4′-bis(carbazol-9-yl)biphenyl (CBP), 2,3,6,7,10,11-hexacyano-1,4,5,8,9,12-hexaazatriphenylene (HATCN), and MoO₃; poly(N-vinylcarbazole) (PVK); poly(2,7-(9,9-di-n-octylfluorene)-(1,4-phenylene((4-sec-butylphenyl)imino)-1,4 phenylene (TFB); and a poly(triphenylamine) derivative (Poly-TPD). Particularly preferable are a tetracyano compound such as TFB, a carbazole derivative such as PVK, and a triallylamine derivative such as Poly-TPD.

The hole-transport layer 4 has a thickness of preferably 15 nm or more and 80 nm or less. If the hole-transport layer 4 has a thickness of less than 15 nm, the holes might not be sufficiently transported by the hole-transport layer 4. Moreover, if the hole-transport layer 4 has a thickness of more than 80 nm, a drive voltage of the light-emitting element 100 rises, possibly resulting in a drastic reduction of current.

The hole-injection layer 2 is disposed between the anode 1 and the hole-transport layer 4, and injects the holes from the anode 1 to the hole-transport layer 4. Alternatively, the hole-injection layer 2 is disposed between the anode and the light-emitting layer 5, and injects the holes from the anode toward the light-emitting layer. The hole-injection layer 2 contains an inorganic hole-transport material (a first inorganic hole-transport material).

Examples of the inorganic hole-transport material include one or more of materials selected from a group of: a metal oxide of any one or more of such metals as Zn, Cr, Ni, Ti, Nb, Al, Si, Mg, Ta, Hf, Zr, Y, La, and Sr; a nitride; or a carbide. Particularly preferable as the inorganic transport material is an oxide containing any one or more of Zn, Cr, Ni, Ti, Nb, Al, Si, Mg, Ta, Hf, Zr, Y, La, and Sr. More preferably, the material is at least one selected from NiO, MgO, MgNiO, LaNiO₃, CuO, or Cu₂O. Moreover, the inorganic hole-transport material may be CuSCN containing a metal and a CN group, a SCN group, or a SeCN group bonding to the metal.

The hole-injection layer 2 has a thickness of preferably 15 nm or more and 100 nm or less. If the hole-injection layer 2 has a thickness of less than 15 nm, the holes might not be sufficiently transported by the hole-injection layer 2. Moreover, if the hole-injection layer 2 has a thickness of more than 100 nm, the hole-injection layer 2 might not be uniformly formed in thickness. This might decrease efficiency in the injection of the holes into the hole-transport layer 4.

The organic layer 3 is disposed between the hole-injection layer 2 and the hole-transport layer 4.

The organic layer 3 contains an aromatic compound A (a first aromatic compound) having: R¹ containing at an end a functional group capable of chemically bonding to the above inorganic hole-transport material; a functional group R² that is a functional group containing at an end at least one functional group selected from a hydrogen atom, a nitro group, a cyano group, a halogen group, a carboxyl group, an aldehyde group, a hydroxyl group, an ester bond with one to three carbons, or an alkyl group and an amid group with one to three carbons; and an aromatic ring to which each of R¹ and R² bonds.

The functional group R¹ preferably contains at an end at least one selected from a carboxyl group, a silanol group, a phosphonate group, a thiol group, or an amino group. Moreover, R¹ may be an alkyl group with one to three carbons; that is, a functional group containing at an end at least one selected from a carboxyl group, a silanol group, a phosphonate group, a thiol group, or an amino group. Furthermore, the aromatic compound A is preferably one selected from a carboxyl group, a silanol group, a phosphonate group, a thiol group, or an amino group directly bonding to the aromatic ring. Such a feature facilitates bonding to the above inorganic hole-transport material. Through the organic layer 3, the holes can be injected with higher efficiency from the hole-injection layer 2 into the hole-transport layer 4.

The functional group R² can be made of the functional groups listed above as the functional group R¹. Preferably, the functional group R² further contains an electron-withdrawing group. Such a feature can further improve efficiency in injection of the holes from the hole-injection layer 2 into the hole-transport layer 4. Among the functional groups listed as the functional group R², the electron-withdrawing group is a functional group containing a nitro group, a cyano group, a carboxyl group, an aldehyde group, or an ester bond with one to three carbons. R² is at least one selected from a nitro group, a cyano group, a carboxyl group, an aldehyde group, or an ester bond with one to three carbons. Preferably, at least one selected from a nitro group, a cyano group, a carboxyl group, an aldehyde group, or an ester bond with one to three carbons directly bonds to the aromatic ring.

The aromatic ring can be selected from at least one of, for example, a benzene ring, a naphthalene ring, an anthracene ring, a pyridine skeleton, or a pyrazine skeleton.

The aromatic compound A is preferably a compound represented by a formula (1) below

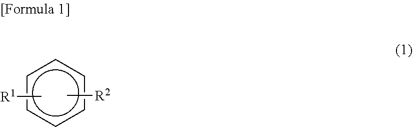

In view of an effect of a dipole moment, the functional group R¹ is preferably in a meta position or a para position of the functional group R². The functional group R¹ is particularly preferable in the para position of the functional group R².

Moreover, the aromatic compound A can form a monolayer film on a surface of the above hole-injection layer 2. The monolayer film formed of this aromatic compound A can be interpreted as the organic layer 3. Hence, in the aromatic compound A; that is, the monolayer film formed on the surface of the hole-injection layer 2, the functional group R¹ bonds to the inorganic hole-transport material in the hole-injection layer 2. The aromatic compound A is oriented so that the functional group R¹ side is positioned toward the hole-injection layer 2. Then, if the functional group R² contains an electron-withdrawing group, the dipole moment of the aromatic compound A is oriented from the hole-transport layer 4 toward the hole-injection layer 2. That is, the functional group R¹ side polarizes toward the positive side. Such a feature can further improve efficiency in injection of the holes from the hole-injection layer 2 into the hole-transport layer 4. Furthermore, the feature can reduce the drive voltage of the light-emitting element 100.

In addition, the functional group R² is at least one functional group selected from a nitro group, a cyano group, a carboxyl group, an aldehyde group, a hydroxyl group, or an amino group. Such a feature can increase hydrophilicity on the surface of the organic film.

Here, if the organic hole-transport material contained in the hole-transport layer 4 is highly hydrophilic as, for example, a polythiophene derivative (disclosed in the Japanese Patent Application Publication No. 2014-067868), the hydrophilicity on the surface of the organic film is increases, so that, even if the organic hole-transport material is high in hydrophilicity, the hole-transport layer can be formed appropriately, making it possible to increase flexibility of the hole transport material.

The organic layer 3 has a thickness of preferably 0.5 nm or more and 1.5 nm or less. If the organic layer 3 has a thickness of less than 0.5 nm, the bonding of the organic layer 3 to the hole-injection layer 2 might be weak. Moreover, if the organic layer 3 has a thickness of more than 1.5 nm, there might be a decrease of the holes to be transported from the hole-injection layer 2 to the hole-transport layer 4. The thickness of the organic layer 3 is 1/150 to 1/10 as great as the thickness of the hole-transport layer 4. If the thickness of the organic layer 3 is smaller than 1/150 the thickness of the hole-transport layer 4, the voltage required to transport the holes in the hole-transport layer 4 increases. This might relatively reduce an advantageous effect of the organic layer 3 to lower the drive voltage, with respect to the entire drive voltage. Moreover, if the thickness of the organic layer 3 is greater than 1/10 the thickness of the hole-transport layer 4, the effect of the dipole moment by the organic 3 inevitably influences on the light-emitting layer. Such an influence might make it difficult to lower the drive voltage.

Here, the thickness of the organic layer means the maximum thickness of any given cross-section of the organic layer cut in the thickness direction of the organic layer. The thickness of the organic layer can be measured by observation of the cross-section of the organic layer, using, for example, a scanning electron microscope (SEM), or a transmission electron microscope (TEM). Note that the thickness of the organic layer does not have to be necessarily uniform. The organic layer may have an uneven thickness. The organic layer may have a relatively thick portion and a relatively thin portion.

Note that, in the present invention, the organic layer does not have to be provided all across neighboring layers. The organic layer does not necessarily have to cover the entire surfaces of the neighboring layers. The organic layer may be shaped into a layer in at least a portion of the neighboring layers. Hence, even if the organic layer is provided, the organic layer does not have to be found between the neighboring layers, and the neighboring layers may have portions in contact with each other.

Specifically, the organic layer may include, for example, a plurality of organic layers each shaped into an island and provided between the neighboring layers. Moreover, the organic layer may include, for example, a plurality of through holes formed in the thickness direction.

On any given cross-section in the thickness direction of the light-emitting element, the organic layer covers preferably 10% or more of the surfaces of the neighboring layers, more preferably 30% or more, still more preferably 50% or more, still more preferably 70% or more, still more preferably 90% or more, and most preferably 100%. Note that, here, the statement that the organic layer covers 100% of the surfaces of the neighboring layers means that the organic layer has a portion to cover for continuously 1 μm in a direction perpendicular to the thickness direction. That is, whether the above percentage is satisfied is found out by measuring within a range of 1 μm in a width perpendicular to the thickness direction of the organic layer to see whether the percentage is sadsfied.

Moreover, the organic layer does not have to have a substantially uniform thickness, and may have asperities and uneven thickness.

The electron-transport layer 6 is disposed between the cathode 7 and the light-emitting layer 5, and transports the electrons from the cathode 7 to the light-emitting layer 5. The electron-transport layer 6 contains an electron-transport material.

Examples of the electron-transport material include a compound or a complex containing one or more nitrogen-containing hetero rings such as an oxadiazole ring, a triazole ring, a triazine ring, a quinolone ring, a phenanthroline ring, a pyrimidine ring, an imidazole ring, and a carbazole ring. Specific examples include. a 1,10-phenanthroline derivative such as bathocuproin or bathophenanthroline; a benzimidazole derivative such as 1,3,5-tris(N-phenylbenzimidazol-2-yl) benzene (TPBI); a metal complex such as a bis(10-quinolinolato)beryllium complex, an 8-hydroxyquinoline Al complex, or bis(2-methyl-8-quinolinolato)-4-phenylphenolate aluminum; and 4,4′-biscarbazolbiphenyl. Otherwise, the examples include: an aromatic boron compound; an aromatic silane compound; an aromatic phosphine compound such as phenyldi(I-pyrenyl)phosphine; bathophenanthroline; bathocuproine; 2,2′,2″-(1,3,5-benzenetriyl)-tris(1-Phenyl-1-H-benzoimidazole) (TPBI); or a nitrogen-containing heteroring compound such as a triazine derivative.

Moreover, the examples include: zinc oxide (ZnO); magnesium zinc oxide (MgZnO); titanium oxide (TiO₂); and strontium oxide (SrTiO₃). These materials may be nanoparticles.

Described below is an example of how to produce the light-emitting element 100 according to this embodiment, with reference to FIGS. 1, 2, and 3. FIG. 2 is a flowchart showing an example of how to produce the light-emitting element 100 according to this embodiment.

First, the anode 1 is formed on, for example, a substrate (S1). The anode 1 can be formed by various kinds of known techniques such as, for example, sputtering and vacuum deposition.

On the anode 1, the hole-injection layer 2 is formed (S2). The anode 2 can be formed by various kinds of known techniques such as, for example, sputtering, vacuum deposition, and coating.

On the hole-injection layer 2, the organic layer 3 is formed (S3). The organic layer 3 can be formed as follows: The hole-injection layer 2 is coated with, or immersed in, the solution containing the aromatic compound A. The aromatic compound A is dried to form the organic layer 3. Note that, after dried, the aromatic compound A may be cleaned.

More specifically, for example, the solution containing the aromatic compound A is brought into contact with the hole-injection layer 2, and left for a predetermined time period. Hence, on the hole-injection layer 2, a monolayer film of the aromatic compound A is formed. After that, the formed monolayer is cleaned and dried.

On the organic layer 3, the hole-transport layer 4 is formed (S4). The hole-transport layer 4 may be formed by various kinds of known techniques such as, for example, sputtering, vacuum deposition, and coating.

On the hole-transport layer 4, the light-emitting layer 5 is formed (S5). The light-emitting layer 5 may be formed by various kinds of known techniques such as, for example, sputtering, vacuum deposition, and coating.

On the light-emitting layer 5, the electron-transport layer 6 is formed (S6). The electron-transport layer 6 can be formed by various kinds of known techniques such as, for example, sputtering, vacuum deposition, and coating.

On the electron-transport layer 6, the cathode 7 is formed (S7). The cathode 7 can be formed by various kinds of known techniques such as, for example, sputtering and vacuum deposition.

Hence, the light-emitting element 100 can be produced.

According to the light-emitting element of this embodiment, the organic layer 3 is provided between the hole-injection layer 2 and the hole-transport layer 4. This organic layer 3 can improve efficiency in injection of the holes from the hole-injection layer 2 into the hole-transport layer 5. Such a feature can improve the luminance of the light-emitting element, and maintain the drive voltage low for the light-emitting element.

Moreover, the aromatic compound A is preferably a molecule having: the R¹; the R²; and an aromatic ring to which each of the R¹ and the R² bonds. Hence, as can be seen, the organic layer can be readily formed as a monolayer film. Furthermore, the aromatic compound A is more preferably a molecule having the R¹ including one R¹ or two R's. Hence, a monolayer film as the organic layer can be formed more densely. Note that, if the aromatic compound A has a plurality of R's, the R's may be the same or different.

### Example 1

First, on a substrate, an anode was formed by sputtering. The anode was made of ITO, and sized by 2 mm×10 mm with a thickness of 30 nm.

Next, 0.249 mg of nickel acetate was dissolved in 5 ml of ethanol to prepare a solution. The anode was coated with 0.1 ml of the solution by spin-coating. Then, the solution was heated in the air at a temperature of 230° C. for one hour, to form a hole-injection layer having a thickness of 45 nm.

Next, the hole-injection layer was immersed in 0.1M of a methanol solution containing benzoic acid for one hour and dried, and an organic layer was formed. The organic layer had a thickness of 0.5 nm.

Next, 8 mg of TFB was dissolved in 1 ml of chlorobenzene to prepare a solution. The organic layer was coated with the solution by spin-coating and dried, so that a hole-transport layer was formed to have a thickness of 35 nm.

Next, 0.1 ml of a QD solution containing quantum dots of CdSe/ZnS (core/shell) was prepared. The hole-transport layer was coated with the QD solution by spin-coating and dried, so that a light-emitting layer was formed to have a thickness of 30 nm. Note that the above quantum dots have a peak emission wavelength of 530 nm (green).

Next, a solution containing ZnO having a particle size of 12 nm was prepared. The light-emitting layer was coated with the solution by spin-coating and dried, so that an electron-transport layer was formed to have a thickness of 45 nm.

Next, on the electron-transport layer, a cathode with a thickness of 100 nm was formed of Al by vacuum deposition.

As can be seen, a light-emitting element according to Example 1 was prepared.

### Example 2

A light-emitting element was prepared as seen in Example 1, except that benzoic acid was replaced with 4-aminobenzoic acid.

### Example 3

A light-emitting element was prepared as seen in Example 1, except that benzoic acid was replaced with 4-nitrobenzoic acid.

### Comparative Example 1

A light-emitting element was prepared as seen in Example 1, except that the organic layer was omitted. That is, on the hole-injection layer containing a metal oxide, the hole-transport layer was formed of an organic hole-transport material.

### Comparative Example 2

A light-emitting element was prepared as seen in Example 1, except that the hole-transport layer was omitted.

### Comparative Example 3

A light-emitting element was prepared as seen in Example 2, except that the hole-transport layer was omitted.

### Comparative Example 4

A light-emitting element was prepared as seen in Example 3, except that the hole-transport layer was omitted.

### Comparative Example 5

A light-emitting element was prepared as seen in Example 1, except that the hole-transport layer was omitted.

### Evaluation

An LED measuring apparatus produced by Spectra Co-op (a two-dimension CCD small high-sensitive spectrometer: Solid Lambda CCD produced by Carl Zeiss) was used to measure the luminance and the drive voltages of each of the light-emitting elements according to Examples and Comparative Examples.

More specifically, to each of the light-emitting elements, a current J (in a more precise sense, a current density) of 0.03 mA/cm² to 75 mA/cm² was applied. When the current was applied, each of the light-emitting elements emitted light. A luminance value L of the light was measured with the above LED measuring apparatus (the spectrometer). Moreover, for each of the light-emitting elements, the voltage J was varied in a range from 0.03 mA/cm² to 75 mA/cm². A drive voltage V (a voltage between the anode and the cathode) was measured for each current J.

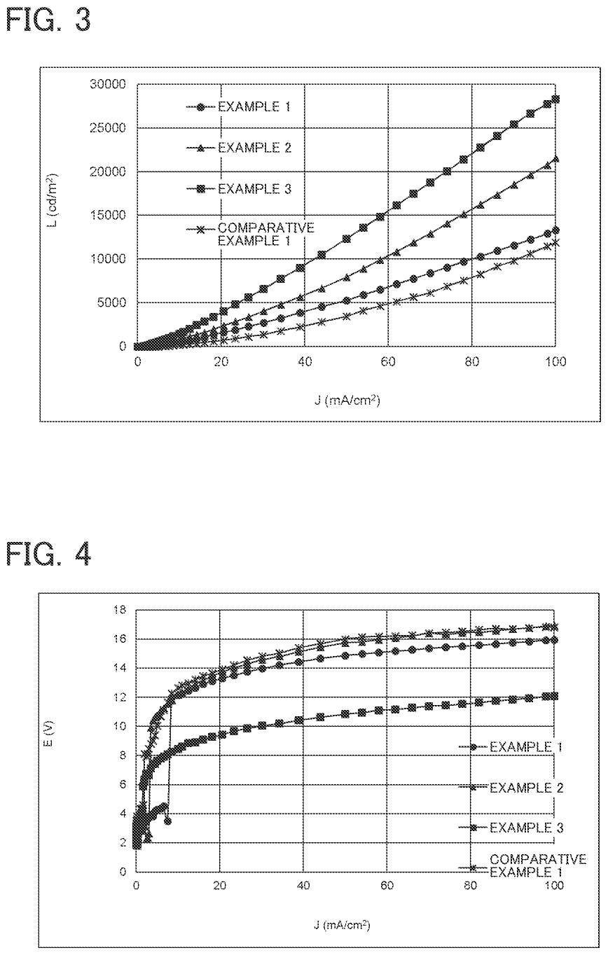

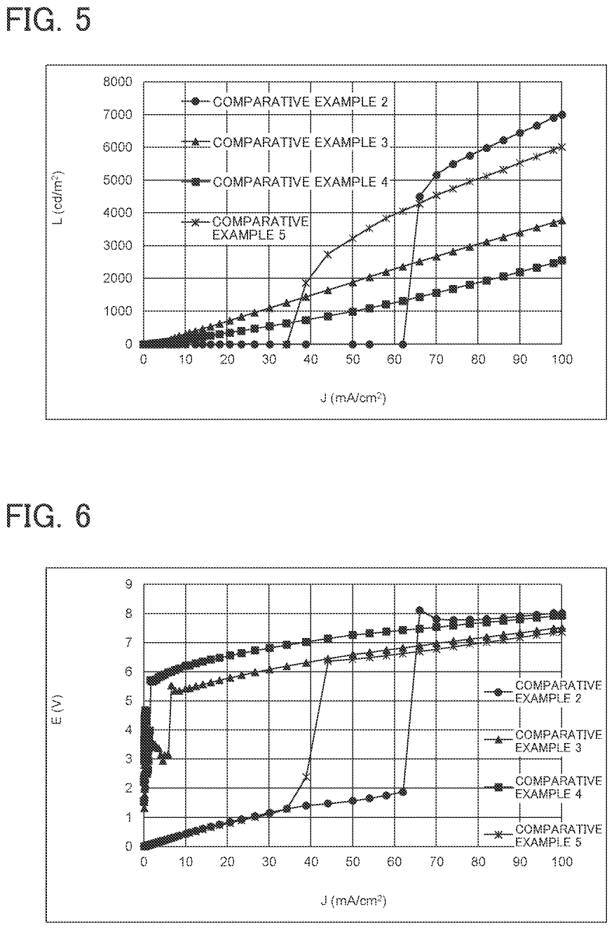

The results are shown in FIGS. 3 to 6. FIG. 3 shows luminance-current characteristics of the light-emitting elements according to Examples 1 to 3 and Comparative Example 1. FIG. 4 shows drive voltage-current characteristics of the light-emitting elements according to Examples 1 to 3 and Comparative Example 1. FIG. 5 shows luminance-current characteristics of the light-emitting elements according to Comparative Examples 2 to 5. FIG. 6 shows drive voltage-current characteristics of the light-emitting elements according to Comparative Examples 2 to 5.

FIGS. 3 and 4 show that the light-emitting elements according to Examples 1 to 3 are higher in luminance, and lower in drive voltage, than the light-emitting element according to Comparative Example 1, and exhibit good performance. This is because of the assumption as follows: When the organic layer is formed, the above functional group R¹ compensates for a defect on the surface of the hole-injection layer formed of the inorganic hole-transport material, so that the defect on the surface decreases. As a result, the holes are injected with higher efficiency from the hole-injection layer into the hole-transport layer. Another assumption is made as follows: The organic layer 3 has a benzene ring (an aromatic ring). Thus, when the organic layer 3 is formed, there is a decrease in energy barrier between the hole-injection layer and the hole-transport layer. As a result, the holes are injected with higher efficiency from the hole-injection layer into the hole-transport layer.

Moreover, the light-emitting element according to Example 3 is higher in luminance, and lower in drive voltage, than the light-emitting elements according to Examples 1 and 2, and exhibits particularly good performance. This is because of the assumption as follows: The above functional group R² contains an electron-withdrawing group, and the functional group R¹ side is polarized toward the positive side. As a result, there is a decrease in energy barrier between the hole-injection layer and the hole-transport layer, and the holes are injected with higher efficiency from the hole-injection layer 2 into the hole-transport layer 4.

Furthermore, FIGS. 5 and 6 show that any of the light-emitting elements according to Comparative Examples 2 to 5 exhibits a significant decrease in luminance with the same drive voltage compared with the light-emitting elements according to Examples 1 to 3 and Comparative Example 1. This shows that if the hole-transport layer is omitted, it is difficult to increase the luminance and the drive voltages of the light-emitting elements.

Moreover, the light-emitting elements provided with organic layers according to Comparative Examples 2 and 3 require a drive voltage higher than, or equal to, the drive voltage of the light-emitting element according to Comparative Example 5. This is because of the assumption as follows: A dipole moment of the organic layers according to Comparative Examples 2 and 3 influences more on accumulating charges in layers (here, the light-emitting layers) in contact with the organic layers and inhibiting carrier injection than on decreasing the energy barrier.

### Second Embodiment

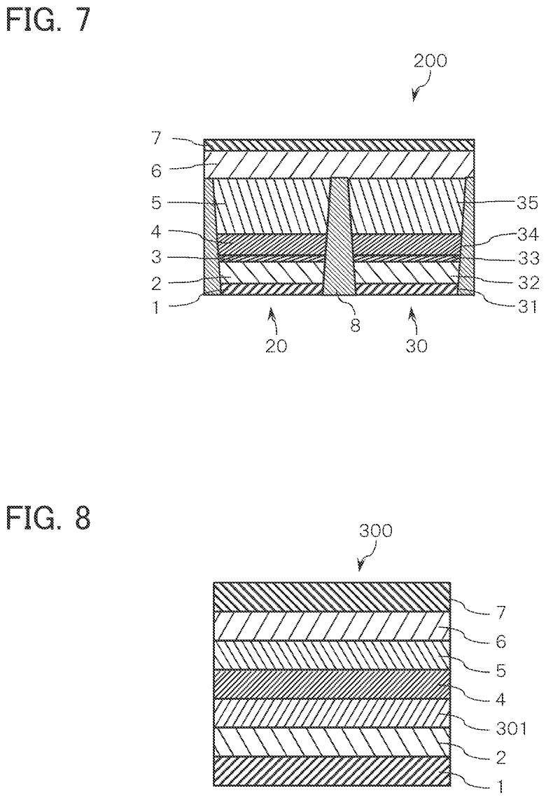

FIG. 7 is a view schematically illustrating an example of a multilayer structure of a light-emitting element 200 according to this embodiment.

As illustrated in FIG. 7, the light-emitting element 200 includes a first light-emitting unit 20 similar to the light-emitting element according to the first embodiment, and additionally includes a light-emitting element having a second light-emitting unit 30. Such a plurality of the light-emitting elements can constitute a display device.

The light-emitting element 200 includes, for example, a second anode 31, a second hole-injection layer 32, a second organic layer 33, a second hole-transport layer 34, a second light-emitting layer 35, the electron-transport layer 6, and the cathode 7, all of which are stacked one another in the stated order. Then, the first light-emitting unit 20 and the second light-emitting unit 30 are segregated by a bank 8. Note that, in this embodiment, the electron-transport layer 6 and the cathode 7 are provided in common between the first light-emitting unit 20 and the second light-emitting unit 30. Alternatively, the electron-transport layer 6 and the cathode 7 may be provided separately for each of the first light-emitting unit 20 and the second light-emitting unit 30. In such a case, the electron-transport layer in the second light-emitting unit 30 is made of the same material as that of the electron-transport layer in the first light-emitting unit 20, and disposed between the second light-emitting layer 35 and the cathode of the second light-emitting unit 30. The electron-transport layer of the second light-emitting unit 30 contains the same electron-transport material as that contained in the electron-transport layer of the first light-emitting unit 20. Furthermore, the cathode of the second light-emitting unit 30 is made of the same material as that of the cathode of the first light-emitting unit 20.

The second anode 31 is made of the same material as that of the anode 1 according to the first embodiment.

The second light-emitting layer 35 is disposed between the second anode 31 and the cathode 7, and emits light a wavelength of which is shorter than a wavelength of light emitted from the light-emitting layer 5. The second light-emitting layer 35 contains a second light-emitting material emitting light a wavelength of which is shorter than a wavelength of light emitted from a light-emitting material (a first light-emitting material) contained in the light-emitting layer 5. Note that the second light-emitting material is the same as the first light-emitting material except for the above points.

The second hole-transport layer 34 is made of the same material as that of the hole-transport layer 4, and disposed between the second light-emitting layer 35 and the second anode 31. The second hole-injection layer 34 contains a second organic hole-transport material identical to the organic hole-transport material (the first organic hole-transport material) contained in the hole-transport layer 4.

The second hole-injection layer 32 is made of the same material as that of the hole-injection layer 2, and disposed between the second hole-transport layer 34 and the second anode 31. The second hole-injection layer 32 contains a second organic hole-transport material identical to the inorganic hole-transport material (the first inorganic hole-transport material) contained in the hole-injection layer 2.

The second organic layer 33 contains, for example, an aromatic compound B (a second aromatic compound) having a functional group R³ capable of chemically bonding to the second inorganic hole-transport material. The aromatic compound B is smaller in dipole moment than the aromatic compound A (the first aromatic compound) contained in the organic layer 3. The dipole moment is oriented from the hole-transport layer toward the hole-injection layer.

The functional group R³ is similar to the functional group R¹, and is preferably at least one selected from a carboxyl group, a silanol group, a phosphonate group, a thiol group, or an amino group. Moreover, R³ may be an alkyl group with one to three carbons; that is, a functional group containing at an end at least one selected from a carboxyl group, a silanol group, a phosphonate group, a thiol group, or an amino group. Furthermore, the aromatic compound A is preferably one selected from a carboxyl group, a silanol group, a phosphonate group, a thiol group, or an amino group directly bonding to the aromatic ring. Such a feature facilitates bonding to the second inorganic hole material. Through the organic layer 33, the holes can be injected with higher efficiency from the hole-injection layer 32 into the hole-transport layer 34.

Moreover, a functional group R⁴ is similar to the functional group R², and includes a functional group containing at an end at least one functional group selected from a hydrogen atom, a nitro group, a cyano group, a halogen group, a carboxyl group, an aldehyde group, or a hydroxy group, an ester bond with one to three carbons, or an alkyl group and an amid group with one to three carbons.

Furthermore, as the functional group R⁴, the functional group R¹ can be made of the functional groups listed above for the functional group R². In addition, preferably, the functional group R⁴ further contains an electron-withdrawing group. Such a feature can further improve efficiency in injection of the holes from the hole-injection layer 2 into the hole-transport layer 4. Among the functional groups listed as the functional group R⁴, the electron-withdrawing group is a functional group containing a nitro group, a cyano group, a carboxyl group, an aldehyde group, or an ester bond with one to three carbons. R⁴ is at least one selected from a nitro group, a cyano group, a carboxyl group, an aldehyde group, or an ester bond with one to three carbons. Preferably, at least one selected from a nitro group, a cyano group, a carboxyl group, an aldehyde group, or an ester bond with one to three carbons directly bonds to the aromatic ring.

Moreover, the aromatic compound B can form a monolayer film on a surface of the above hole-injection layer 32. The monolayer film formed by the aromatic compound B can be interpreted as the organic layer 33. Hence, in the aromatic compound B; that is, the monolayer film formed on the surface of the hole-injection layer 32, the functional group R³ bonds to the inorganic hole-transport material in the hole-injection layer 32. The aromatic compound B is oriented so that the functional group R³ side is positioned toward the hole-injection layer 32. Then, if the functional group R⁴ contains an electron-withdrawing group, a dipole moment of the aromatic compound B is oriented from the hole-transport layer 34 toward the hole-injection layer 32. That is, the functional group R³ side polarizes toward the positive side. Such a feature can further improve efficiency in injection of the holes from the hole-injection layer 32 into the hole-transport layer 34. Furthermore, the feature can reduce the drive voltage of the light-emitting element 200.

The aromatic compound B is preferably a compound represented by a formula (2) below.

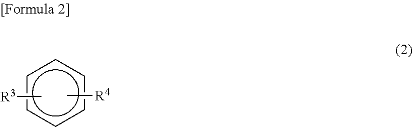

In view of the dipole moment, the functional group R³ is preferably in a meta position or a para position of the functional group R¹. The functional group R³ is particularly preferable in the para position of the functional group R⁴.

Moreover, the aromatic compound B is preferably higher in acid dissociation constant than the aromatic compound A. Hence, the dipole moment, of the second aromatic compound B, oriented from the hole-transport layer toward the hole-injection layer is adjusted preferably smaller than the dipole moment of the aromatic compound A.

Moreover, if a combination of the aromatic compound A and the aromatic compound B is denoted with (the aromatic compound A/the aromatic compound B), examples of the combination include (4-nitrobenzoic acid/4-cyanobenzoic acid), (4-nitrobenzoic acid/4-bromobenzoic acid), (4-nitrobenzoic acid/benzoic acid), (benzoic acid/4-aminobenzoic acid), and (4-methoxybenzoic acid/4-aminobenzoic acid).

According to the light-emitting element 200 of this embodiment, a carrier balance can be adjusted between the holes and the electrons of the first light-emitting layer and the second light-emitting layer, making it possible to improve emission characteristics. In particular, if the first light-emitting material and the second light-emitting material are quantum dots, an emission wavelength of the second light-emitting material is shorter than that of the first light-emitting material, and the conduction band minimum (CBM) of the second light-emitting material is lower than that of the first light-emitting material. If the holes are equally supplied to the first light-emitting layer and the second light-emitting layer, the holes are supplied to the second light-emitting layer with higher efficiency. Hence, the holes could be excessive in the second light-emitting layer. In contrast, in the light-emitting element 200 according to this embodiment, the dipole moment, of the second aromatic compound, oriented from the hole-transport layer toward the hole-injection layer is smaller than the dipole moment of the first aromatic compound. Hence, the efficiency in supply of the holes is lower from the second hole-injection layer to the second hole-transport layer than from the first hole-injection layer to the first hole-transport layer, and less holes are supplied to the second light-emitting layer than to the first light-emitting layer. Thus, the carrier balance can be adjusted between the first light-emitting layer and the second light-emitting layer, making it possible to improve emission characteristics.

Moreover, in the light-emitting element according to this embodiment, between the first light-emitting unit 20 and the second light-emitting unit 30, the anodes, the hole-injection layers, the hole-transport layers, the electron-transport layers, and the cathodes are made of the same materials, and it is not necessary to adjust carrier transportation characteristics due to the compositions and the crystallizability of each of the layers. Such a feature can prevent an increase in extra efforts for producing the light-emitting element 200.

Note that the anodes, the hole-injection layers, the organic layers, the hole-transport layers, the light-emitting layers, the electron-transport layers, and the cathodes may be defective, such that, for example, there is a missing portion in a layer. The layers do not have to be complete ones.

### Example 4

A light-emitting element was prepared as seen in Example 3, except that 4-nitrobenzoic acid was replaced with 4-bromobenzoic acid, and that the light-emitting material was replaced to have quantum dots with a short emission wavelength; specifically, the light-emitting material having a peak emission wavelength of 530 nm (green) was replaced with another light-emitting material having a peak emission wavelength of 460 nm (blue).

### Reference Example 1

A light-emitting element was prepared as seen in Example 4, except that 4-bromobenzoic acid was replaced with 4-nitrobenzoic acid.

### Results

The light-emitting element of Example 4 obtained an emission characteristic (specifically luminance) similar to that of the light-emitting element of Example 3. That is, if the light-emitting element 200 according to this embodiment includes: the light-emitting element of Example 3 as the first light-emitting unit 20 according to this embodiment; and the light-emitting element of Example 4 as the second light-emitting unit 30 according to this embodiment, the luminance can be kept in balance between the first light-emitting unit and the second light-emitting unit so that the entire light-emitting element can improve in emission characteristic. Note that, in the second organic layer, 4-bromobenzoic acid is smaller in dipole moment oriented from the hole-transport layer toward the hole-injection layer than 4-nitrobenzoic acid.

Meanwhile, the light-emitting element of Reference Example 1 obtained an emission characteristic lower than emission characteristics of the light-emitting elements of Reference Example 1 and Example 3. That is, if the light-emitting element 200 according to this embodiment includes: the light-emitting element of Example 3 as the first light-emitting unit 20 according to this embodiment; and the light-emitting element of Reference Example 1 as the second light-emitting unit 30 according to this embodiment, it would be difficult to keep the luminance in balance between the first light-emitting unit and the second light-emitting unit.

### Third Embodiment

A light-emitting element 300 according to this embodiment is, for example, as illustrated in FIG. 8, the light-emitting element according to the first embodiment with the organic layer 3 replaced with an organic layer 301. More specifically, in forming the organic layer 301, the aromatic compound A used to form the organic layer 3 is replaced with a hole-transport compound. Note that like constituent features have like reference signs between this embodiment and the above embodiments. Such constituent features may not be elaborated upon here.

That is, the organic layer 301 of the light-emitting element 300 according to this embodiment contains, for example, a hole-transport compound having. R⁵ containing at an end a functional group capable of chemically bonding to the first inorganic hole-transport material in the hole-injection layer 2; and a functional group R transporting the holes.

The functional group R⁵ contains at an end, for example, at least one selected from a carboxyl group, a silanol group, a phosphonate group, a thiol group, or an amino group. Preferably, R⁵ is at least one group selected from a carboxyl group, a silanol group, a phosphonate group, a thiol group, or an amino group. Such a feature allows easy bonding to the above inorganic hole materials. Note that R⁵ is similar to above R².

The hole-transport compound can be a first compound represented by, for example, an expression (3) below:

R⁶—R¹ (3)

The functional group R⁶ is a functional group transporting the holes. Examples of R⁶ include functional groups having at least one skeleton selected from carbazole, tetracyano, triallylamine, thiophene, fluorine, quinonediimide, phthalocyanine, triphenylene, or phenylnaphthalene. Such a feature can further improve efficiency in injection of the holes from the hole-injection layer 2 into the hole-transport layer 5. Moreover, the feature can also reduce the voltage and the power consumption of the light-emitting element 100.

Furthermore, the above hole-transport compound can be the first compound containing: R⁵; and the functional group R⁶ having at least one skeleton selected from carbazole, tetracyano, triallylamine, thiophene, fluorine, quinonediimide, phthalocyanine, triphenylene, or phenylnaphthalene.

In addition, a more preferable hole-transport compound is represented by, for example, an expression (4) below:

R⁷—R⁶—R⁵ (4)

The functional group R¹ contains at an end at least one selected from, for example, a hydrogen atom, an ester bond with one to three carbons, or an alkyl group with one to three carbons. The functional group R¹ is selected preferably from a hydrogen atom, an ester bond with one to three carbons, or an alkyl group with one to three carbons. Moreover, the functional group R may include one, or two or more functional groups R⁷ to bond to R. Such a feature can further improve efficiency in injection of the holes from the hole-injection layer 2 into the hole-transport layer 5. Furthermore, the feature can further reduce the voltage and the power consumption of the light-emitting element 100.

In addition, the hole-transport compound is preferably a molecule having at least the R⁵ and the R⁶. Thanks to such a feature, as described above, the organic layer can readily be formed as a monolayer film. Moreover, the hole-transport compound is more preferably a molecule having the R⁵ including one R⁵ or two R⁵ s. Thanks to such a feature, a monolayer film as the organic layer can be formed more densely. Note that, if the hole-transport compound has two R⁵s, the R⁵s may be the same or different.

Furthermore, the organic layer 301 according to this embodiment has a thickness of preferably 0.5 nm or more and 3 nm or less. If the organic layer 301 has a thickness of 0.5 nm or more, the organic layer 301 can bond more firmly to the hole-injection layer 2 than the organic layer 301 formed thinly. In addition, if the organic layer 301 has a thickness of 3 nm or less, the organic layer 301 can transport the holes from the hole-injection layer 2 to the hole-transport layer 4 more than the organic layer 301 formed thickly.

According to the light-emitting element of this embodiment, the organic layer 301 is provided between the hole-injection layer 2 and the hole-transport layer 4. This organic layer 301 can improve efficiency in injection of the holes from the hole-injection layer 2 into the hole-transport layer 5. Such a feature can improve the luminance of the light-emitting element, while maintaining the drive voltage low for the light-emitting element.

### Example 5

The organic layer of Example 1 was formed by immersing, for five seconds or longer, in an ethanol solution containing 0.01 M of the hole-transport compound represented by an expression (5) below and drying the ethanol solution. The organic layer had a thickness of 1.2 nm. Otherwise, a light-emitting element was prepared as seen in Example 1.

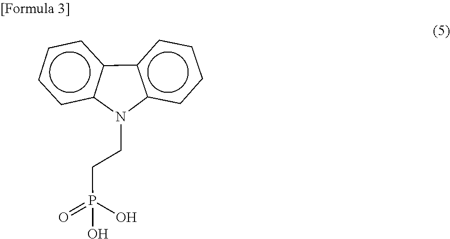

### Example 6

A light-emitting element was prepared as seen in Example 5, except that the hole-transport compound represented by the expression (5) was replaced with a hole-transport compound represented by an expression (6) below:

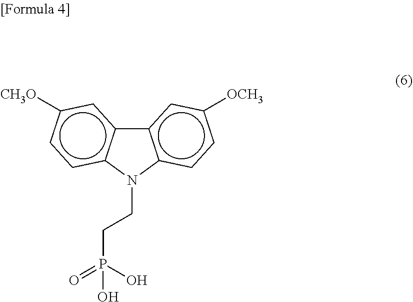

### Comparative Example 6

A light-emitting element was prepared as seen in Example 5, except that the organic layer was omitted That is, on the hole-injection layer containing a metal oxide, the hole-transport layer was formed of an organic hole-transport material.

### Evaluation

As seen in the first embodiment, the luminance and the drive voltage were measured for each of the light-emitting elements in the Examples and Comparative Examples. Moreover, the power consumption P(=J×V) was obtained from the current J and the drive voltage V.

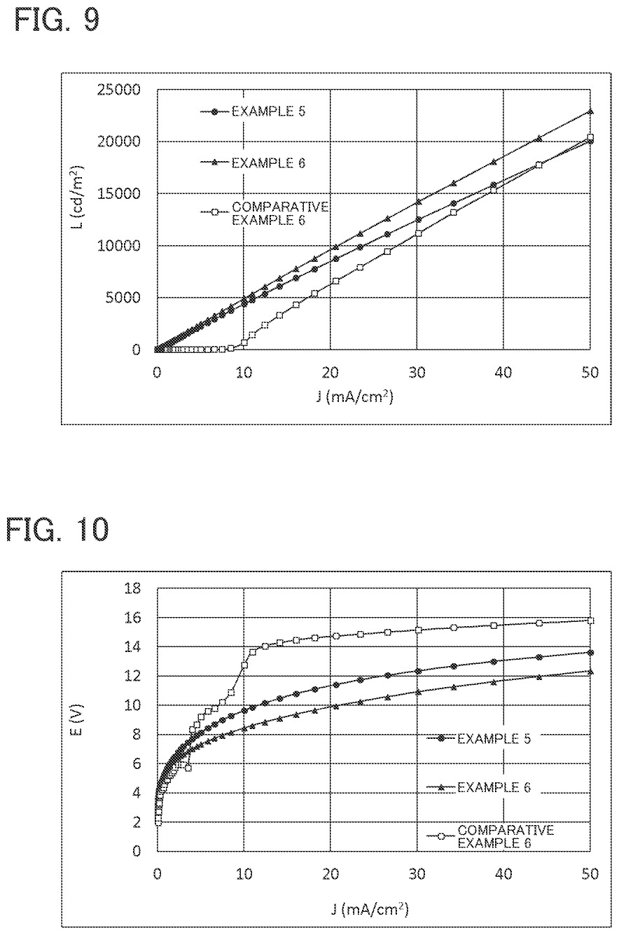

The results are shown in FIGS. 8 to 10. FIG. 8 shows luminance-current characteristics of the light-emitting elements according to Examples 5 to 6 and Comparative Example 6. FIG. 9 shows drive voltage-current characteristics of the light-emitting elements according to Examples 5 to 6 and Comparative Example 6. FIG. 10 shows luminance-power consumption of the light-emitting elements according to Examples 5 to 6 and Comparative Example 6.

FIG. 8 shows that the light-emitting elements according to Examples 5 and 6 exhibit an improvement in luminance-current characteristics, compared with the light-emitting element according to Comparative Example 6 except for the luminance at 50 mA/cm² according to Example 5. Moreover, FIG. 9 shows that the light-emitting elements according to Examples 5 and 6 exhibit a reduction in voltage with respect to the same current density, compared with the light-emitting element according to Comparative Example 6. Furthermore, FIG. 10 shows that the light-emitting elements according to Examples 5 and 6 exhibit an improvement; that is, a reduction in consumption of the power for obtaining the same luminance as that of the light-emitting element according to Comparative Example 6.

This is because of the assumption as follows: When the organic layer 301 is formed, the functional group R⁵ compensates for a defect on the surface of the hole-injection layer 2 formed of the inorganic hole-transport material, so that the defect on the surface decreases. As a result, the holes are injected with higher efficiency from the hole-injection layer into the hole-transport layer. Specifically, it is assumed that the a hole-transport compound—PO₄H₂ contained in the organic layer 301 and represented by the expressions (6) and (7) and Ni²⁺ of NiO contained in the hole-injection layer 2 bond together to compensate for the above defect on the surface.

Moreover, the following is assumed: The organic layer 301 contains the functional group R⁶ transporting the holes. Hence, the holes transported from the hole-injection layer 2 are smoothly injected into the hole-transport layer 4, thereby reducing the risk that the holes are trapped to the defect remaining on the surface of the hole-injection layer 2. This is why the holes are injected with higher efficiency from the hole-injection layer 2 into the hole-transport layer 4.

Moreover, FIGS. 8 to 10 show that the light-emitting element according to Example 6 is higher in luminance, and lower in voltage and power consumption, than the light-emitting element according to Example 5.

This is because of the assumption as follows. In the organic layer 301 formed of the hole-transport compound represented by the expression (7), a methoxy group is found closer to the hole-transport layer 4. Hence, the hole-transport layer 4 and the organic layer 301 come into contact more closely.

### Fourth Embodiment

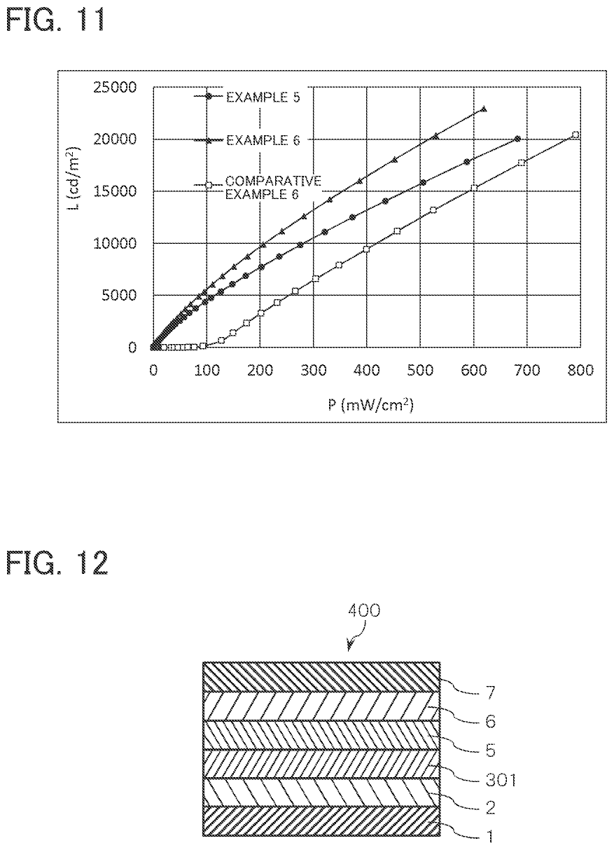

A light-emitting element 400 according to this embodiment is, for example, as illustrated in FIG. 11, the light-emitting element 300 according to the third embodiment without the hole-transport layer 4. Note that like constituent features have like reference signs between this embodiment and the above embodiments. Such constituent features may not be elaborated upon here.

In other words, the light-emitting element according to this embodiment includes: a first anode; a first cathode facing the first anode; a first light-emitting layer disposed between the first anode and the first cathode, and containing a first light-emitting material; a first hole-injection layer disposed between the first anode and the first light-emitting layer, and containing a first inorganic hole-transport material; and a third organic layer disposed between the first light-emitting layer and the first hole-injection layer. The third organic layer contains a hole-transport compound having: R⁵ containing at an end a functional group capable of chemically bonding to the first inorganic hole-transport material; and a functional group R⁶ transporting the holes.

Furthermore, the organic layer 301 according to this embodiment has a thickness of preferably 0.5 nm or more and 3 nm or less. If the organic layer 301 has a thickness of 0.5 nm or more, the organic layer 301 can bond more firmly to the hole-injection layer 5 than the organic layer 301 formed thinly. In addition, if the organic layer 301 has a thickness of 3 nm or less, the organic layer 301 can transport the holes from the hole-injection layer 2 to the hole-transport layer more than the organic layer 301 formed thickly.

According to the above configuration, the organic layer 301 allows efficient injection of the holes from the hole-injection layer 2 into the light-emitting layer 4.

According to the light-emitting element of this embodiment, the organic layer 301 is provided between the hole-injection layer 2 and the light-emitting layer 5. This organic layer 301 can improve efficiency in injection of the holes from the hole-injection layer 2 into the light-emitting layer 5. Such a feature can improve the luminance of the light-emitting element, while maintaining the drive voltage low for the light-emitting element.

### Example 7

A light-emitting element was prepared as seen in Example 5, except that the hole-transport layer was omitted.

### Example 8

A light-emitting element was prepared as seen in Example 6, except that the hole-transport layer was omitted.

### Comparative Example 7

A light-emitting element was prepared as seen in Example 7, except that the organic layer was omitted.

### Evaluation

Evaluations were made as seen in the third embodiment.

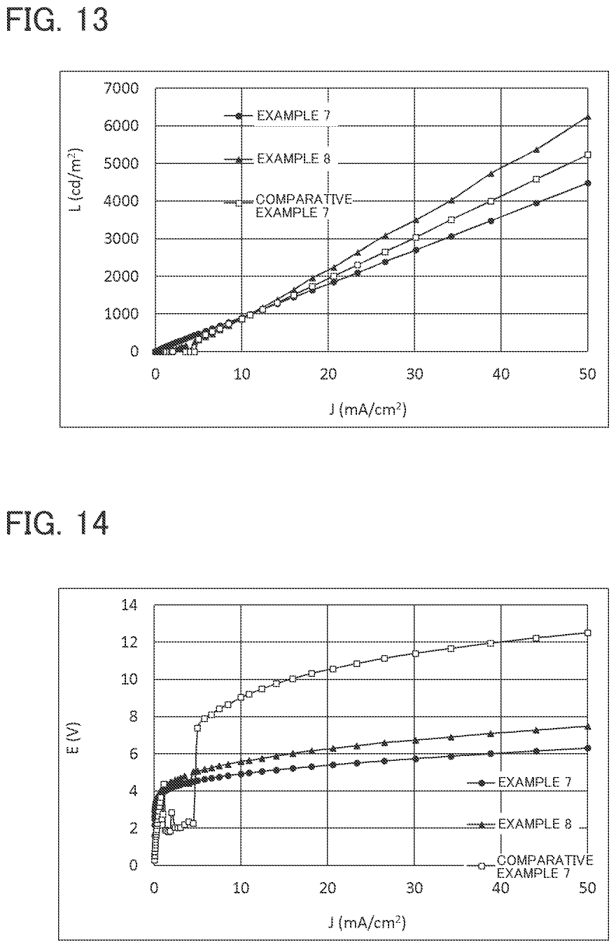

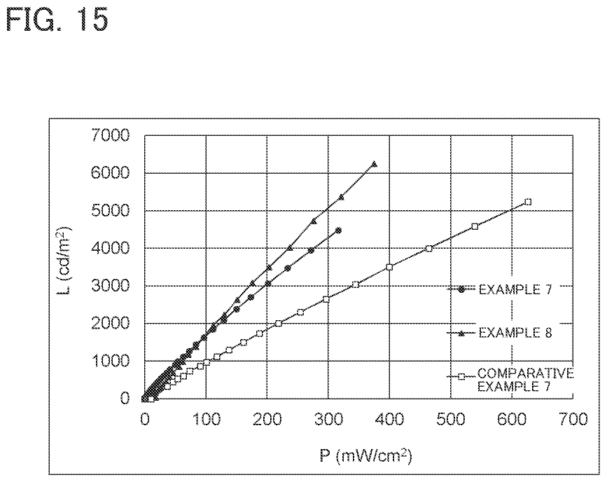

The results are shown in FIGS. 12 to 14. FIG. 12 shows luminance-current characteristics of the light-emitting elements according to Examples 7 and 8, and Comparative Example 7. FIG. 13 shows drive voltage-current characteristics of the light-emitting elements according to Examples 7 and 8, and Comparative Example 7. FIG. 14 shows luminance-power consumption of the light-emitting elements according to Examples 7 and 8 and Comparative Example 7.

FIG. 12 shows that the light-emitting element according to Example 8 exhibits an improvement in luminance-current characteristics, compared with the light-emitting element according to Comparative Example 7. FIG. 13 shows that the light-emitting elements according to Examples 7 and 8 exhibit a reduction in voltage with respect to the same current density, compared with the light-emitting element according to Comparative Example 7. Furthermore, FIG. 14 shows that the light-emitting elements according to Examples 7 and 8 exhibit an improvement; that is, a reduction in consumption of the power for obtaining the same luminance as that of the light-emitting element according to Comparative Example 7.

The light-emitting elements according to Examples 7 and 8 each include the organic layer 301 between the hole-injection layer 2 and the light-emitting layer 5. The organic layer 301 contains: a functional group capable of chemically bonding to an inorganic hole-transport material contained in the hole-injection layer 2; and a functional group transporting the holes.

This is because of the assumption as follows: When the organic layer 301 is formed, the functional group R⁵ compensates for a defect on the surface of the hole-injection layer 2 formed of the inorganic hole-transport material, so that the defect on the surface decreases. As a result, the holes are injected with higher efficiency from the hole-injection layer 2 into the light-emitting layer 5. Specifically, it is assumed that the a hole-transport compound—PO₄H2 contained in the organic layer 301 and represented by the expressions (6) and (7) and Ni²⁺ of NiO contained in the hole-injection layer 2 bond together to compensate for the above defect on the surface.

Moreover, the following is assumed: The organic layer 301 contains the functional group R⁶ transporting the holes. Hence, the holes transported from the hole-injection layer 2 are smoothly injected into the light-emitting layer 5, thereby reducing the risk that the holes are trapped to the defect remaining on the surface of the hole-injection layer 2. This is why the holes are injected with higher efficiency from the hole-injection layer 2 into the light-emitting layer 5.

Furthermore, FIGS. 12 to 14 show that, in a low current region, the light-emitting element in Example 7 is higher in luminance, and lower in voltage and power consumption, than the light-emitting element in Example 8. This is because of the assumption as follows. In the organic layer 301, the functional group R⁷ transporting the holes is found closer to the organic hole-transport layer. Hence, the organic layer 301 and the light-emitting layer 5 come into contact more closely.

The present invention shall not be limited to the above embodiments. The features of the above embodiments may be replaced with substantially the same features, with features having the same advantageous effects, or with features to achieve the same object.

1. A light-emitting element, comprising:
a first anode;
a first cathode facing the first anode;
a first light-emitting layer disposed between the first anode and the first cathode, and containing a first light-emitting material;
a first hole-transport layer disposed between the first light-emitting layer and the first anode, and containing a first organic hole-transport material;
a first hole-injection layer disposed between the first anode and the first hole-transport layer, and containing a first inorganic hole-transport material; and
a first organic layer disposed between the first hole-transport layer and the first hole-injection layer,
wherein the first organic layer contains a first aromatic compound having: a functional group R¹ containing at an end a functional group capable of chemically bonding to the first inorganic hole-transport material; a functional group R² that is a functional group containing at an end at least one selected from a hydrogen atom, a nitro group, a cyano group, a halogen group, a carboxyl group, an aldehyde group, a hydroxyl group, an ester bond with one to three carbons, an alkyl group with one to three carbons or an amid group; and an aromatic ring to which each of the functional group R¹ and the functional group R² bonds.

2. The light-emitting element according to claim 1,
wherein the functional group R¹ contains at an end at least one selected from a carboxyl group, a silanol group, a phosphonate group, a thiol group, or an amino group.

3. (canceled)

4. (canceled)

5. The light-emitting element according to claim 1,
wherein the first aromatic compound is represented by a formula (1) below:

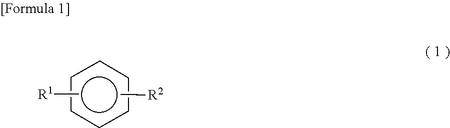

6-12. (canceled)

13. The light-emitting element according to claim 1,
the first organic layer has a thickness of 0.5 nm or more and 1.5 nm or less.

14. (canceled)

15. (canceled)

16. The light-emitting element according to claim 1, further comprising:
a second anode;
a second cathode facing the second anode;
a second light-emitting layer disposed between the second anode and the second cathode, and containing a second light-emitting material a wavelength of which is shorter than a wavelength of the first light-emitting material;
a second hole-transport layer disposed between the second light-emitting layer and the second anode, and containing a second organic hole-transport material;
a second hole-injection layer disposed between the second anode and the second hole-transport layer, and containing a second inorganic hole-transport material; and
a second organic layer disposed between the second hole-transport layer and the second hole-injection layer,
wherein the second organic layer contains a second aromatic compound having a functional group R³ capable of chemically bonding to the second inorganic hole-transport material, the second aromatic compound being smaller in dipole moment than the first aromatic compound, and the dipole moment being oriented from a hole-transport layer toward a hole-injection layer.

17. The light-emitting element according to claim 16,
wherein at least one pair of the first anode and the second anode, the first hole-injection layer and the second hole-injection layer, the first hole-transport layer and the second hole-transport layer, and the first cathode and the second cathode is made of a same material.

18. The light-emitting element according to claim 16, further comprising:
a first electron-transport layer disposed between the first light-emitting layer and the first cathode; and
a second electron-transport layer disposed between the second light-emitting layer and the second cathode,
wherein the first electron-transport layer and the second electron-transport layer, and/or the first cathode and the second cathode are provided in common.

19. (canceled)

20. (canceled)

21. A light-emitting element, comprising:
a first anode;
a first cathode facing the first anode;
a first light-emitting layer disposed between the first anode and the first cathode, and containing a first light-emitting material;
a first hole-injection layer disposed between the first anode and the first light-emitting layer, and containing a first inorganic hole-transport material;
a third organic layer disposed between the first light-emitting layer and the first hole-injection layer;
a first hole-transport layer disposed between the first light-emitting layer and the third organic layer, and containing a first organic hole-transport material,
wherein the third organic layer contains a hole-transport compound having: R⁵ containing at an end a functional group capable of chemically bonding to the first inorganic hole-transport material; and R⁶ that is a functional group transporting holes.

22-37. (canceled)

38. A light-emitting element, comprising:
a first anode;
a first cathode facing the first anode;
a first light-emitting layer disposed between the first anode and the first cathode, and containing a first light-emitting material;
a first hole-injection layer disposed between the first anode and the light-emitting layer, and containing a first inorganic hole-transport material;
a third organic layer disposed between the light-emitting layer and the first hole-injection layer; and
a first hole-transport layer disposed between the first light-emitting layer and the third organic layer, and containing a first organic hole-transport material
wherein the third organic layer includes a first compound containing: a functional group R⁵ containing at an end at least one selected from a carboxyl group, a silanol group, a phosphonate group, a thiol group, or an amino group; and a functional group R⁶ having at least one skeleton selected from carbazole, tetracyano, triallylamine, thiophene, fluorine, quinonediimide, phthalocyanine, triphenylene, or phenylnaphthalene.

39. The light-emitting element according to claim 38,
wherein the first compound further has a functional group R⁷ that is a functional group containing at an end at least one selected from a hydrogen atom, an ester bond with one to three carbons, or an alkyl group with one to three carbons.

40. The light-emitting element according to claim 39,
wherein the functional group R⁷ is a functional group selected from a hydrogen atom, an ester bond with one to three carbons, or an alkyl group with one to three carbons.

41. The light-emitting element according to claim 39,
wherein the third organic layer is thinner than the first hole-transport layer in a stacking direction.

42. The light-emitting element according to claim 38,
wherein the first inorganic hole-transport material is a metal oxide.

43. The light-emitting element according to claim 42,
wherein the metal oxide is at least one selected from NiO, MgO, MgNiO, LaNiO₃, CuO, or Cu₂O.

44. The light-emitting element according to claim 38,
wherein the third organic layer is thinner than the first hole-injection layer in a stacking direction.

45. The light-emitting element according to claim 38,
wherein the third organic layer has a thickness of 0.5 nm or more and 3 nm or less.

46. The light-emitting element according to claim 38, further comprising
a first hole-transport layer disposed between the first light-emitting layer and the third organic layer, and containing a first organic hole-transport material.

47. The light-emitting element according to claim 46,
wherein the first organic hole-transport material contains at least one selected from a tetracyano compound, a carbazole derivative, or a triallylamine derivative.

48-50. (canceled)

51. The light-emitting element according to claim 38,
wherein the first compound is a molecule having at least the R⁵ and the R⁶.

52. The light-emitting element according to claim 51,
wherein the first compound is a molecule having the R⁵ including one R⁵ or two R⁵s.
